(19) United States
(12) Patent Application Publication
(10) Pub. No.: US 2026/0282377 A1
(43) Pub. Date: Sep. 17, 2026

(54) METHOD OF MANUFACTURING SEMICONDUCTOR DEVICE

(71) Applicant: Kioxia Corporation, Minato-ku, Tokyo (JP)

(72) Inventors: Hiroshi ITOKAWA, Kuwana Mie (JP); Hidekazu HAYASHI, Yokkaichi Mie (JP)

(73) Assignee: Kioxia Corporation, Minato-ku, Tokyo (JP)

(21) Appl. No.: 19/238,681

(22) Filed: Jun. 16, 2025

(30) Foreign Application Priority Data
Mar. 11, 2025 (JP) 2025-038625

(51) Int. Cl. H01L 23/00; H01L 21/78; H01L 25/18; H10B 43/10; H10B 43/35; H10B 51/10; H10B 51/30; H10B 80/00; H10D 80/30

(52) U.S. Cl. CPC H10B 51/30; H10B 43/35; H10P 54/00; H10B 43/10; H10B 51/10; H10B 80/00; H10D 80/30; H10W 72/0198; H10W 80/312; H10W 80/327; H10W 80/701; H10W 90/00; H10W 90/792

(57) ABSTRACT

A method of manufacturing a semiconductor device (MD) includes the steps of: alternately stacking a first layer (161) mainly composed of a component whose extinction coefficient in an infrared region is greater than that of silicon and a second layer (162) mainly composed of silicon oxide on a first wafer (SS), and thereby forming a stacked portion (160); forming a first element (MCA) and a first bonding electrode (P_{I1}) in the first wafer; forming a second element (Tr) and a second bonding electrode (P_{I2}) in a second wafer (SB); bonding the first wafer and the second wafer via the first bonding electrode and the second bonding electrode; and transmitting a laser light through a first substrate (150) to irradiate the stacked portion with the laser light, and thereby induce cleavage in the stacked portion.

### CROSS-REFERENCE TO RELATED APPLICATIONS

This application is based upon and claims the benefit of Japanese Patent Application No. 2025-038625, filed on Mar. 11, 2025, the entire contents of which are incorporated herein by reference.

### BACKGROUND

### Field

The present embodiments relate to methods of manufacturing a semiconductor device.

### Description of the Related Art

There is known a method of manufacturing a semiconductor device, including bonding a wafer having a substrate and a certain layer and another wafer, and irradiating the certain layer with a laser light to detach the substrate.

### BRIEF DESCRIPTION OF THE DRAWINGS

FIG. 1 is a schematic circuit diagram showing a part of a configuration of a semiconductor device according to a first embodiment;

FIG. 2 is a schematic exploded perspective view showing a configuration example of same semiconductor device;

FIG. 3 is a schematic bottom view showing a configuration example of a chip C_{M} included in same semiconductor device;

FIG. 4 is a schematic cross-sectional view showing a part of a configuration of same semiconductor device;

FIG. 5 is a schematic cross-sectional view showing a part of a configuration of same semiconductor device;

FIG. 6 is a schematic bottom view showing a part of a configuration of the chip C_{M};

FIG. 7 is a schematic cross-sectional view showing a part of a configuration of the chip C_{M};

FIG. 8 is a schematic cross-sectional view for explaining a method of manufacturing a semiconductor device according to the first embodiment;

FIG. 9 is a schematic cross-sectional view for explaining same method of manufacturing;

FIG. 10 is a schematic cross-sectional view for explaining same method of manufacturing;

FIG. 11 is a schematic bottom view for explaining same method of manufacturing;

FIG. 12 is a schematic bottom view for explaining same method of manufacturing;

FIG. 13 is a schematic cross-sectional view for explaining same method of manufacturing;

FIG. 14 is a schematic cross-sectional view for explaining same method of manufacturing;

FIG. 15 is a schematic cross-sectional view for explaining same method of manufacturing;

FIG. 16 is a schematic cross-sectional view for explaining same method of manufacturing;

FIG. 17 is a schematic cross-sectional view for explaining same method of manufacturing;

FIG. 18 is a schematic cross-sectional view for explaining same method of manufacturing;

FIG. 19 is a schematic top view for explaining same method of manufacturing;

FIG. 20 is a schematic cross-sectional view for explaining same method of manufacturing;

FIG. 21 is a schematic cross-sectional view for explaining same method of manufacturing;

FIG. 22 is a schematic cross-sectional view for explaining same method of manufacturing;

FIG. 23 is a schematic cross-sectional view for explaining same method of manufacturing;

FIG. 24 is a schematic cross-sectional view for explaining same method of manufacturing;

FIG. 25 is a schematic cross-sectional view for explaining same method of manufacturing;

FIG. 26 is a schematic cross-sectional view for explaining same method of manufacturing;

FIG. 27 is a schematic top view for explaining same method of manufacturing;

FIG. 28 is a schematic top view for explaining same method of manufacturing;

FIG. 29 is a schematic cross-sectional view for explaining a method of manufacturing a semiconductor device according to a second embodiment;

FIG. 30 is a schematic cross-sectional view for explaining same method of manufacturing;

FIG. 31 is a schematic cross-sectional view for explaining same method of manufacturing;

FIG. 32 is a schematic cross-sectional view for explaining same method of manufacturing;

FIG. 33 is a schematic cross-sectional view for explaining same method of manufacturing; and

FIG. 34 is a schematic cross-sectional view for explaining a method of manufacturing a semiconductor device according to a third embodiment.

### DETAILED DESCRIPTION

A method of manufacturing a semiconductor device according to one embodiment includes the steps of: alternately stacking a first layer mainly composed of a component whose extinction coefficient in an infrared region is greater than that of silicon and a second layer mainly composed of silicon oxide on a first wafer having a first substrate, and thereby forming a stacked portion in the first wafer; forming a first element and a first bonding electrode in the first wafer; forming a second element and a second bonding electrode in a second wafer; bonding the first wafer and the second wafer via the first bonding electrode and the second bonding electrode; and transmitting a laser light through the first substrate to irradiate the stacked portion with the laser light, and thereby induce cleavage in the stacked portion.

Next, methods of manufacturing a semiconductor device according to embodiments will be described in detail with reference to the drawings. Note that the following embodiments are merely examples, and are not shown with the intention of limiting the present invention. Moreover, the following drawings are schematic, and, for convenience of description, a part of a configuration, and so on, thereof will sometimes be omitted. Moreover, portions that are common to a plurality of embodiments will be assigned with the same symbols, and descriptions thereof sometimes omitted.

Moreover, when a “semiconductor device” is referred to in the present specification, it will sometimes mean a semiconductor memory device, and will sometimes mean a semiconductor device other than a semiconductor memory device. Moreover, when a “semiconductor memory device” is referred to in the present specification, it will sometimes mean a memory die, and will sometimes mean a memory system including a controller die, of the likes of a memory chip, a memory card, or an SSD (Solid State Drive). Furthermore, it will sometimes mean a configuration including a host computer, of the likes of a smartphone, a tablet terminal, or a personal computer.

Moreover, in the present specification, when a first configuration is said to be “electrically connected” to a second configuration, the first configuration may be connected to the second configuration directly, or the first configuration may be connected to the second configuration via the likes of a wiring, a semiconductor member, or a transistor. For example, in the case of three transistors having been connected in series, the first transistor is still “electrically connected” to the third transistor even when the second transistor is in an OFF state.

Moreover, in the present specification, when a first configuration is said to be “connected between” a second configuration and a third configuration, it will sometimes mean that the first configuration, the second configuration, and the third configuration are connected in series, and the second configuration is connected to the third configuration via the first configuration.

Moreover, in the present specification, when a circuit, or the like, is said to “make electrically conductive” two wirings, or the like, this will sometimes mean, for example, that this circuit, or the like, includes a transistor, or the like, that this transistor, or the like, is provided in a current path between the two wirings, and that this transistor, or the like, is in an ON state.

Moreover, in the present specification, a certain direction parallel to an upper surface of a substrate will be referred to as an X-direction, a direction parallel to the upper surface of the substrate and perpendicular to the X-direction will be referred to as a Y-direction, and a direction perpendicular to the upper surface of the substrate will be referred to as a Z-direction.

Moreover, in the present specification, a direction lying along a certain plane will sometimes be referred to as a first direction, a direction intersecting the first direction along the certain plane will sometimes be referred to as a second direction, and a direction intersecting the certain plane will sometimes be referred to as a third direction. These first direction, second direction, and third direction may correspond to any of the X-direction, the Y-direction, and the Z-direction, but need not do so.

Moreover, in the present specification, expressions such as “above” or “below” will be defined with reference to the substrate. For example, an orientation of moving away from the substrate along the above-described Z-direction will be referred to as above, and an orientation of coming closer to the substrate along the Z-direction will be referred to as below. Moreover, when a lower surface or a lower end is referred to for a certain configuration, this will be assumed to mean a surface or end portion on a substrate side of this configuration, and when an upper surface or an upper end is referred to for a certain configuration, this will be assumed to mean a surface or end portion on an opposite side to the substrate of this configuration. Moreover, a surface intersecting the X-direction or the Y-direction will be referred to as a side surface, and so on.

Moreover, in the present specification, when the likes of a “width”, a “length”, or a “thickness” in a certain direction is referred to for a configuration, a member, and so on, this will sometimes mean a width, a length, or a thickness, and so on, in a cross section observed by the likes of SEM (Scanning Electron Microscopy) or TEM (Transmission Electron Microscopy), and so on.

Moreover, in the present specification, when a “wiring” is referred to, this will sometimes include the likes of a wiring, a contact electrode, a connecting portion for connecting a wiring and a contact electrode, or a bonding electrode.

### First Embodiment

### Circuit Configuration of Memory Die MD

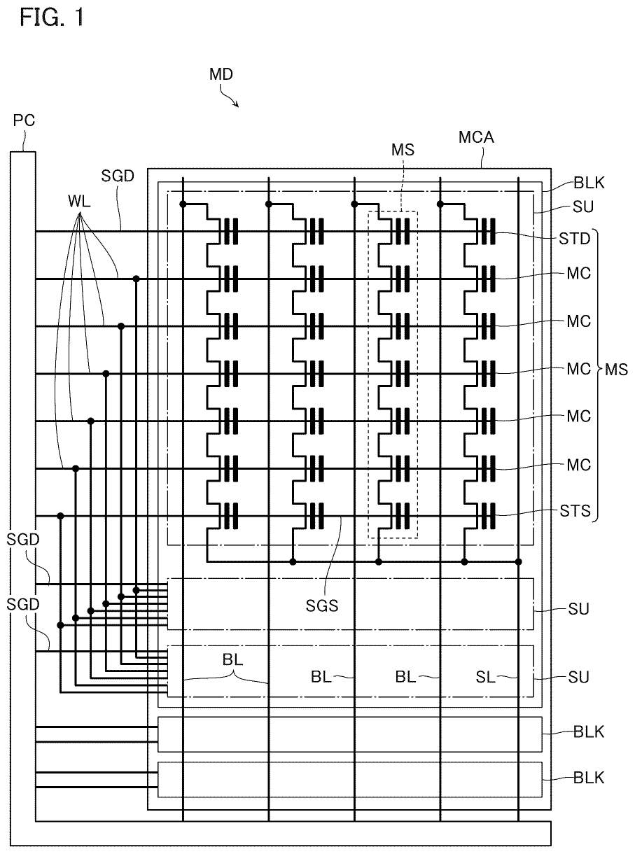

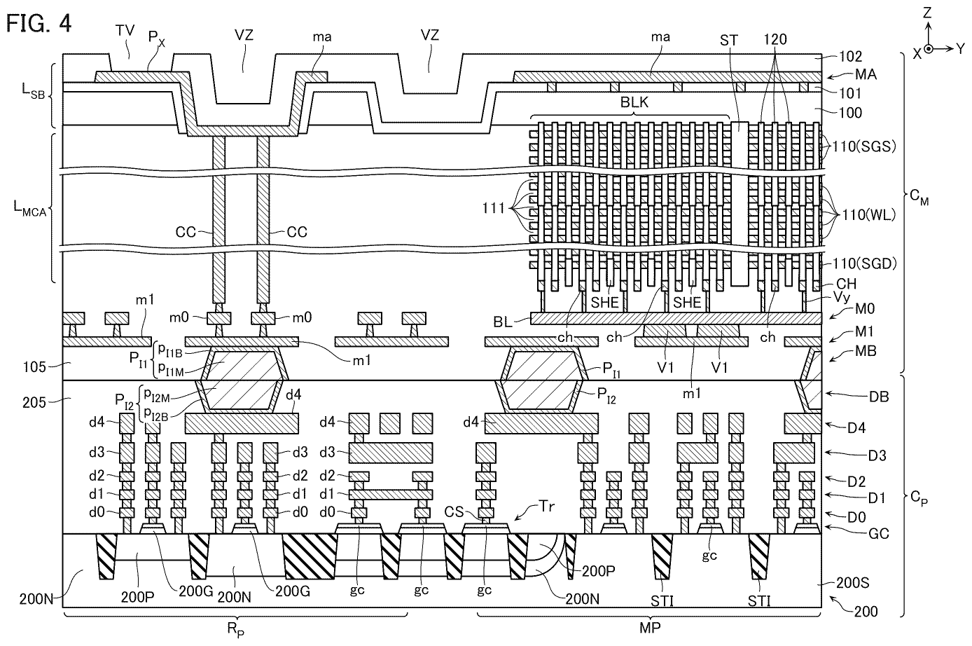

FIG. 1 is a schematic circuit diagram showing a part of a configuration of a semiconductor device according to a first embodiment. In the first embodiment, a memory die MD is exemplified as one example of the semiconductor device. As shown in FIG. 1, the memory die MD comprises a memory cell array MCA and a peripheral circuit PC. The memory cell array MCA is one example of a first element. Moreover, the peripheral circuit PC comprises a plurality of transistors Tr (refer to FIG. 4). These plurality of transistors Tr are one example of a second element.

### Circuit Configuration of Memory Cell Array MCA

As shown in FIG. 1, the memory cell array MCA comprises a plurality of memory blocks BLK. These plurality of memory blocks BLK each comprise a plurality of string units SU. These plurality of string units SU each comprise a plurality of memory strings MS. One ends of these plurality of memory strings MS are each connected to the peripheral circuit PC via bit lines BL. Moreover, the other ends of these plurality of memory strings MS are each connected to the peripheral circuit PC via a common source line SL.

The memory string MS comprises a drain side select transistor STD, a plurality of memory cells MC (memory transistors), and a source side select transistor STS. The drain side select transistor STD, the plurality of memory cells MC, and the source side select transistor STS are connected in series between the bit line BL and the source line SL. Hereafter, the drain side select transistor STD and the source side select transistor STS will sometimes simply be referred to as select transistors (STD, STS).

The memory cell MC is a field effect type transistor. The memory cell MC comprises a semiconductor layer, a gate insulating film, and a gate electrode. The semiconductor layer functions as a channel region. The gate insulating film includes an electric charge accumulating film. A threshold voltage of the memory cell MC changes according to an amount of charge in the electric charge accumulating film. The memory cell MC stores 1 bit or a plurality of bits of data. Note that the gate electrodes of the plurality of memory cells MC corresponding to one memory string MS are each connected with word lines WL. These word lines WL are each commonly connected to all of the memory strings MS in one memory block BLK.

The select transistors (STD, STS) are field effect type transistors. The select transistors (STD, STS) each comprise a semiconductor layer, a gate insulating film, and a gate electrode. The semiconductor layer functions as a channel region. The gate insulating film may include an electric charge accumulating film. The gate electrode of the drain side select transistor STD is connected with a drain side select gate line SGD, and the gate electrode of the source side select transistor STS is connected with a source side select gate line SGS. One drain side select gate line SGD is commonly connected to all of the memory strings MS in one string unit SU. One source side select gate line SGS is commonly connected to all of the memory strings MS in one memory block BLK.

### Structure of Memory Die MD

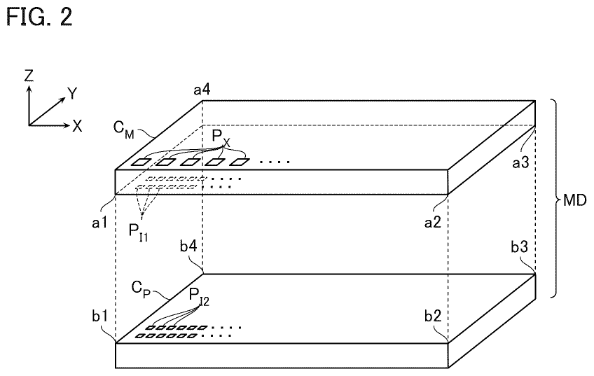

FIG. 2 is a schematic exploded perspective view showing a configuration example of the semiconductor device according to the first embodiment. As shown in FIG. 2, the memory die MD comprises: a chip C_{M} on a memory cell array MCA side; and a chip C_{P} on a peripheral circuit PC side.

An upper surface of the chip C_{M} is provided with a plurality of external pad electrodes P_{X} connectable to unillustrated bonding wires. Moreover, a lower surface of the chip C_{M} is provided with a plurality of bonding electrodes (first bonding electrodes) P_{I1}. Moreover, an upper surface of the chip C_{P} is provided with a plurality of bonding electrodes P_{I2}. Hereafter, a surface provided with the plurality of bonding electrodes P_{I1}, of the chip C_{M} will be referred to as a front surface of the chip C_{M}, and a surface provided with the plurality of external pad electrodes P_{X}, of the chip C_{M} will be referred to as a back surface of the chip C_{M}. Moreover, a surface provided with the plurality of bonding electrodes P_{I2}, of the chip C_{P} will be referred to as a front surface of the chip C_{P}, and a surface on an opposite side to the front surface, of the chip C_{P} will be referred to as a back surface of the chip C_{P}. In the example illustrated, the front surface of the chip C_{P} is provided above the back surface of the chip C_{P}, and the back surface of the chip C_{M} is provided above the front surface of the chip C_{M}.

The chip C_{M} and the chip C_{P} are disposed so that the front surface of the chip C_{M} and the front surface of the chip C_{P} face each other. The plurality of bonding electrodes P_{I1} are each provided correspondingly to the plurality of bonding electrodes (second bonding electrodes) P_{I2}, and are disposed at positions enabling them to be bonded to the plurality of bonding electrodes P_{I2}. The bonding electrodes P_{I1} and bonding electrodes P_{I2} function as bonding electrodes for bonding and making electrically conductive the chip C_{M} and chip C_{P}.

Note that in the example of FIG. 2, corners a1, a2, a3, a4 of the chip C_{M} respectively correspond to corners b1, b2, b3, b4 of the chip C_{P}.

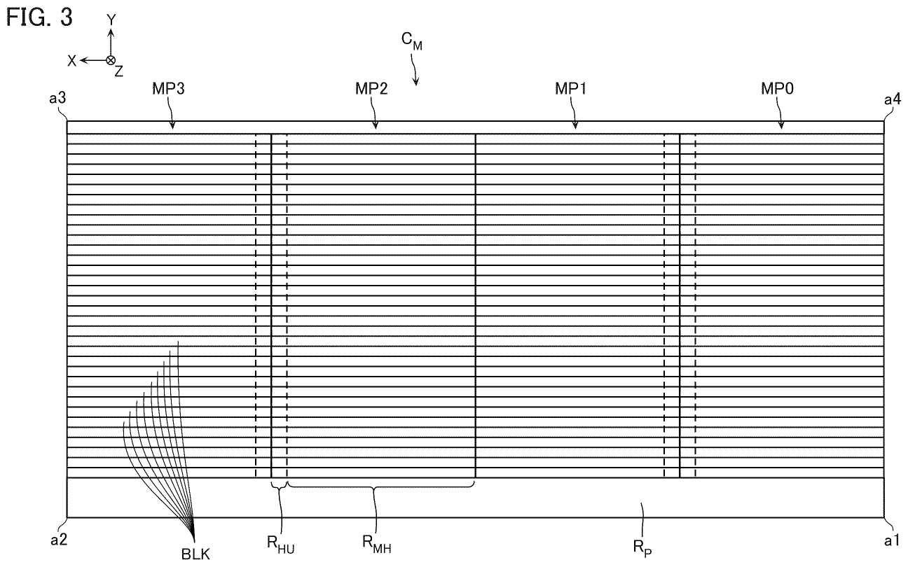

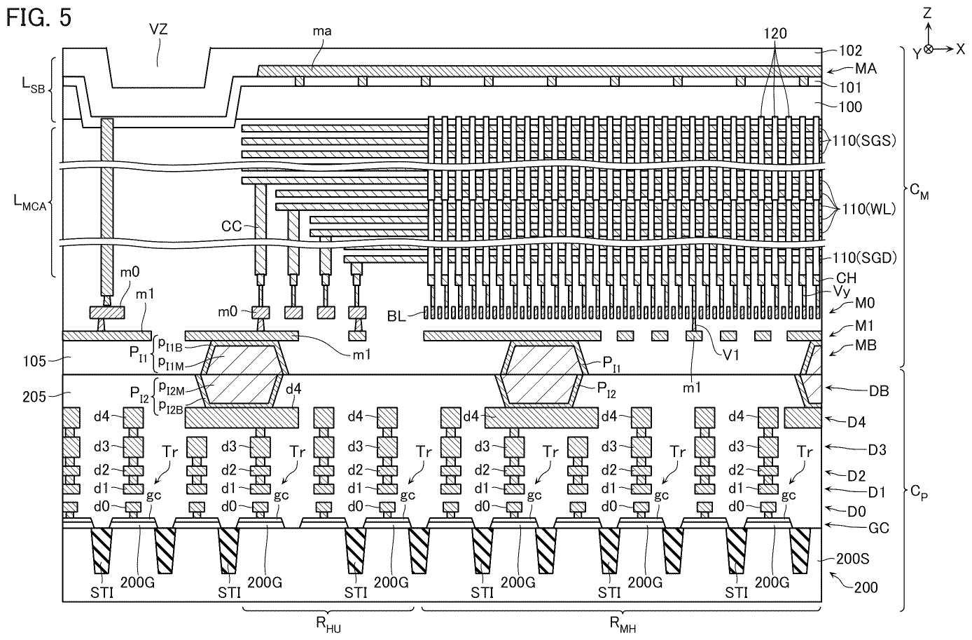

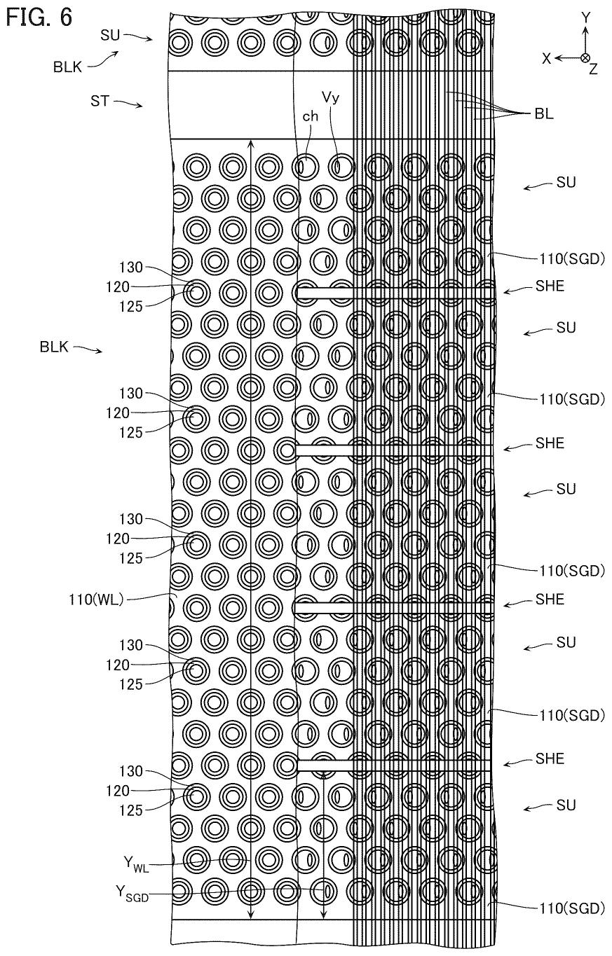

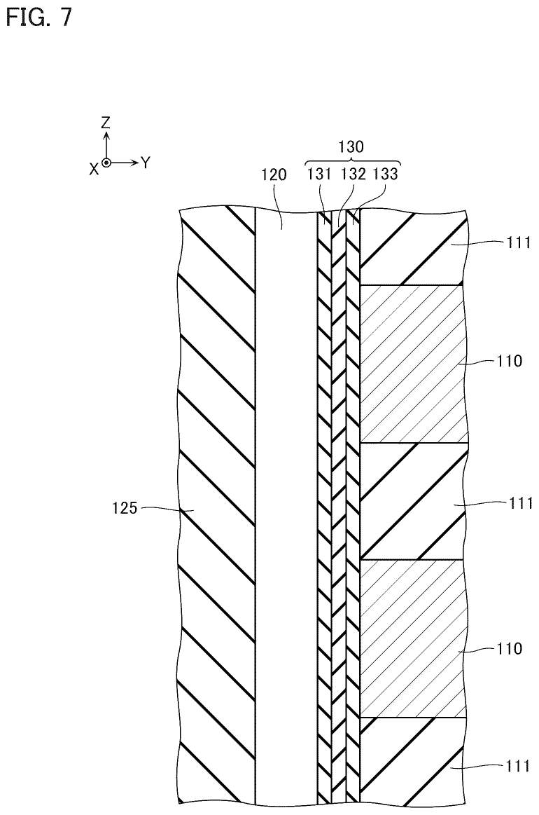

FIG. 3 is a schematic bottom view showing a configuration example of the chip C_{M}. In FIG. 3, a part of a configuration such as the bonding electrodes P_{I1} are omitted. FIGS. 4 and 5 are schematic cross-sectional views showing a part of a configuration of the semiconductor device according to the first embodiment. FIG. 6 is a schematic bottom view showing a part of a configuration of the chip C_{M}. In FIG. 6, a region on the left side shows an XY cross section at a position of the word lines WL, and a region on the right side shows an XY cross section at a position of the drain side select gate line SGD. Note that in order to indicate connecting portions of semiconductor columns 120 and the bit lines BL, the region on the right side of FIG. 6 also shows contact electrodes ch, Vy and the bit lines BL. The contact electrodes ch, Vy and the bit lines BL are also provided in the region on the left side of FIG. 6. FIG. 7 is a schematic cross-sectional view showing a part of a configuration of the chip C_{M}. Although FIG. 7 shows a YZ cross section, a similar structure to in FIG. 7 will be observed, even in the case where a cross section other than a YZ cross section (for example, an XZ cross section) along a central axis of the semiconductor column 120 has been observed.

### Structure of Chip C_{M}

In the example of FIG. 3, the chip C_{M} comprises four memory planes MP0-MP3 arranged in the X-direction. Note that sometimes, the four memory planes MP0-MP3 will each simply be referred to as a memory plane MP. Moreover, these four memory planes MP0-MP3 each comprise a plurality of the memory blocks BLK arranged in the Y-direction. Moreover, in the example of FIG. 3, these four memory planes MP0-MP3 each comprise: a memory hole region R_{MH} (a memory region); and a hook-up region R_{HU} provided on one side in the X-direction with respect to the memory hole region R_{MH}. Moreover, the chip C_{M} comprises a peripheral region R_{P} provided further to a side at one end in the Y-direction of the chip C_{M} than the four memory planes MP0-MP3.

Note that in the example illustrated, the hook-up region R_{HU} is provided on one side in the X-direction with respect to the memory hole region R_{MH}. However, such a configuration is merely an exemplification, and a specific configuration may be appropriately adjusted. For example, the hook-up region R_{HU} may be provided on both sides in the X-direction with respect to the memory hole region R_{MH}. Moreover, the hook-up region R_{HU} may be provided at a center position or near center position in the X-direction of the memory plane MP.

As shown in FIG. 4, for example, the chip C_{M} comprises: a substrate layer L_{SB}; a memory cell array layer L_{MCA} provided below the substrate layer L_{SB}; a contact electrode layer CH provided below the memory cell array layer L_{MCA}; a plurality of wiring layers M0, M1 provided below the contact electrode layer CH; and a chip bonding electrode layer MB provided below the wiring layers M0, M1.

### Structure of Substrate Layer L_{SB} of Chip C_{M}

As shown in FIG. 4, for example, the substrate layer L_{SB} comprises: a conductive layer 100 provided on an upper surface of the memory cell array layer L_{MCA}; an insulating layer 101 provided on an upper surface of the conductive layer 100; a back surface wiring layer MA provided on an upper surface of the insulating layer 101; and an insulating layer 102 provided on an upper surface of the back surface wiring layer MA.

The conductive layer 100 may include a semiconductor layer of the likes of silicon (Si) implanted with an N-type impurity such as phosphorus (P) or P-type impurity such as boron (B), may include a metal of the likes of tungsten (W), or may include a silicide of the likes of tungsten silicide (WSi), for example.

The conductive layer 100 functions as part of the source line SL (FIG. 1). Four conductive layers 100 are provided correspondingly to the four memory planes MP0-MP3 (FIG. 3). End portions in the X-direction and Y-direction of the memory plane MP are provided with a region VZ that does not include the conductive layer 100.

The insulating layer 101 includes the likes of silicon oxide (SiO₂), for example.

The back surface wiring layer MA includes a plurality of wirings ma. These plurality of wirings ma may include the likes of aluminum (Al), for example.

A part of the plurality of wirings ma function as part of the source line SL (FIG. 1). Four of these wirings ma are provided correspondingly to the four memory planes MP0-MP3 (FIG. 3). This wiring ma is electrically connected to a respective conductive layer 100.

Moreover, a part of the plurality of wirings ma function as the external pad electrode P_{X}. This wiring ma is provided in the peripheral region R_{P}. This wiring ma is connected to a contact electrode CC within the memory cell array layer L_{MCA} in the region VZ not including the conductive layer 100. Moreover, part of the wiring ma is exposed to outside of the memory die MD via an opening TV provided in the insulating layer 102.

The insulating layer 102 is a passivation layer consisting of an insulating material such as a polyimide, for example.

### Structure in Memory Hole Region R_{MH} of Memory Cell Array Layer L_{MCA} of Chip C_{M}

As described with reference to FIG. 3, the memory cell array layer L_{MCA} is provided with a plurality of the memory blocks BLK arranged in the Y-direction. As shown in FIG. 4, an inter-block insulating layer ST of the likes of silicon oxide (SiO₂) is provided between two memory blocks BLK adjacent in the Y-direction.

A shown in FIG. 4, for example, the memory block BLK comprises: a plurality of conductive layers 110 arranged in the Z-direction (a stacking direction) (that are stacked in the stacking direction intersecting a later-mentioned first substrate 150); and a plurality of the semiconductor columns 120 extending in the Z-direction. Moreover, as shown in FIG. 7, a gate insulating film 130 is provided between each of the plurality of conductive layers 110 and the plurality of semiconductor columns 120.

The conductive layer 110 comprises a substantially plate-like shape extending in the X-direction. The conductive layer 110 may be mainly composed of tungsten (W) or molybdenum (Mo), for example. Moreover, the conductive layer 110 may be mainly composed of the likes of polycrystalline silicon including an impurity such as phosphorus (P) or boron (B), for example. Moreover, the conductive layer 110 may be mainly composed of titanium nitride (TiN). An inter-layer insulating layer 111 of the likes of silicon oxide (SiO₂) is provided between the plurality of conductive layers 110 arranged in the Z-direction.

One or a plurality of conductive layers 110 located in the uppermost layer, of the plurality of conductive layers 110 function as the gate electrodes of the source side select transistors STS (FIG. 1) and as the source side select gate line SGS (refer to FIG. 4). These plurality of conductive layers 110 are electrically independent every memory block BLK.

Moreover, the plurality of conductive layers 110 located below these uppermost conductive layers 110 function as the gate electrodes of the memory cells MC (FIG. 1) and as the word lines WL. These plurality of conductive layers 110 are each electrically independent every memory block BLK.

Moreover, one or a plurality of conductive layers 110 located below these word line WL-functioning conductive layers 110, function as the gate electrodes of the drain side select transistors STD (FIG. 1) and as the drain side select gate line SGD. As shown in FIG. 6, for example, width Y_{SGD} in the Y-direction of these plurality of conductive layers 110 is less than width Y_{WL} in the Y-direction of the conductive layers 110 functioning as the word lines WL. Moreover, an inter-string unit insulating layer SHE of the likes of silicon oxide (SiO₂) is provided between two conductive layers 110 adjacent in the Y-direction.

As shown in FIG. 6, for example, the semiconductor columns 120 are arranged in a certain pattern in the X-direction and the Y-direction. The respective semiconductor columns 120 function as channel regions of the plurality of memory cells MC and select transistors (STD, STS) included in one memory string MS (FIG. 1). The semiconductor column 120 is mainly composed of polycrystalline silicon (Si). The semiconductor column 120 has a substantially cylindrical shape, and has its central portion provided with an insulating layer 125 of the likes of silicon oxide. An outer peripheral surface of the semiconductor column 120 is surrounded by each of a plurality of the conductive layers 110, and faces these plurality of conductive layers 110.

Moreover, an upper end of the semiconductor column 120 is provided with an unillustrated impurity region. This impurity region is connected to the above-described conductive layer 100 (refer to FIG. 4). This impurity region includes an N-type impurity such as phosphorus (P) or a P-type impurity such as boron (B), for example.

Moreover, a lower end of the semiconductor column 120 is provided with an unillustrated impurity region. This impurity region is connected to the bit line BL via the contact electrode ch and the contact electrode Vy. This impurity region includes an N-type impurity such as phosphorus (P), for example.

As shown in FIG. 6, for example, the gate insulating film 130 has a substantially cylindrical shape covering the outer peripheral surface of the semiconductor column 120. The gate insulating film 130 includes an electric charge accumulating film or a ferroelectric film.

In the case of the gate insulating film 130 including a ferroelectric film, the gate insulating film 130 comprises, for example: a ferroelectric film 132 of substantially cylindrical shape, extending in the Z-direction over a range in the Z-direction corresponding to the plurality of conductive layers 110, along the outer peripheral surface of the semiconductor column 120; an insulating film 131 of substantially cylindrical shape, extending in the Z-direction over a range in the Z-direction corresponding to the plurality of conductive layers 110, along an inner peripheral surface of the ferroelectric film 132; and an insulating film 133 of substantially cylindrical shape, extending in the Z-direction over a range in the Z-direction corresponding to the plurality of conductive layers 110, along an outer peripheral surface of the ferroelectric film 132.

The ferroelectric film 132 is mainly composed of at least one of silicon (Si), aluminum (Al), hafnium (Hf), and zirconium (Zr). The ferroelectric film 132 may be an insulating film including orthorhombic hafnium oxide, for example. The hafnium oxide included in the ferroelectric film 132 may be mainly orthorhombic. More specifically, the hafnium oxide included in the ferroelectric film 132 may be mainly type III orthorhombic (orthorhombic III, space group Pbc21, space group number 29). A proportion accounted for by orthorhombic crystals may be greatest among crystals of hafnium oxide included in the ferroelectric film 132. Note that orthorhombic is also referred to as orthorhombic. Crystalline structure in the ferroelectric film 132 is observable by a method such as ACOM-TEM (Automated Crystal Orientation Mapping Transmission Electron Microscopy), for example.

Moreover, the ferroelectric film 132 can include at least one added element selected from the group consisting of silicon (Si), zirconium (Zr), aluminum (Al), yttrium (Y), strontium (Sr), lanthanum (La), samarium (Sm), gadolinium (Gd), terbium (Tb), dysprosium (Dy), holmium (Ho), erbium (Er), ytterbium (Yb), lutetium (Lu), and barium (Ba). Hereafter, such an added element will sometimes be referred to as a “first added element”. Note that presence and concentration of the added element can be confirmed by a method such as EDX (Energy Dispersive X-ray Spectroscopy), for example.

From a viewpoint of manifesting ferroelectric characteristics in the hafnium oxide, concentration of the above-described first added element is preferably between 0.1 atomic % and 80 atomic % inclusive. Appropriate range of concentration of the above-described first added element for manifesting ferroelectric characteristics in the hafnium oxide differs according to a kind of the first added element. For example, when the first added element is silicon (Si), then the appropriate range of concentration of the first added element for manifesting ferroelectric characteristics will be between 3 atomic % and 7 atomic % inclusive. For example, when the first added element is barium (Ba), then the appropriate range of concentration of the first added element for manifesting ferroelectric characteristics will be between 0.1 atomic % and 3 atomic % inclusive. For example, when the first added element is zirconium (Zr), then the appropriate range of concentration of the first added element for manifesting ferroelectric characteristics will be between 10 atomic % and 80 atomic % inclusive.

In the case of the gate insulating film 130 including an electric charge accumulating film, the gate insulating film 130 may comprise a film capable of accumulating a charge, of the likes of silicon nitride (SiN), instead of the above-described ferroelectric film 132.

### Structure in Hook-Up Region R_{HU} of Memory Cell Array Layer L_{MCA} of Chip C_{M}

As shown in FIG. 5, the hook-up region R_{HU} is provided with a plurality of terrace portions of the conductive layers 110(WL, SGD, SGS). The terrace portion is a portion of a lower surface of a conductive layer 110 that, viewed from below, does not overlap another conductive layer 110. Below the plurality of conductive layers 110 is filled in by an insulating layer 105 mainly composed of silicon oxide. In addition, the hook-up region R_{HU} is provided with a plurality of the contact electrodes CC. These plurality of contact electrodes CC each extend in the Z-direction penetrating the insulating layer 105, and are connected at their upper ends to the terrace portions of the conductive layers 110(WL, SGD, SGS).

### Structure in Peripheral Region R_{P} of Memory Cell Array Layer L_{MCA} of Chip C_{M}

As shown in FIG. 4, for example, the peripheral region R_{P} is filled in by the insulating layer 105. Moreover, a plurality of the contact electrodes CC are provided in the peripheral region R_{P}, correspondingly to the external pad electrodes P_{X}. These plurality of contact electrodes CC each extend in the Z-direction penetrating the insulating layer 105, and are connected at their upper ends to the external pad electrode P_{X}.

### Structure of Contact Electrode Layer CH of Chip C_{M}

The contact electrode layer CH is filled in by the insulating layer 105. Moreover, the contact electrode layer CH is provided with a plurality of the contact electrodes ch. These plurality of contact electrodes ch each extend in the Z-direction penetrating the insulating layer 105, and are electrically connected to either or both of configurations in the memory cell array layer L_{MCA} and configurations in the chip C_{P}, for example.

The contact electrode layer CH includes the plurality of contact electrodes ch as a plurality of wirings. These plurality of contact electrodes ch may include for example a stacked film having stacked therein a barrier conductive film of the likes of titanium nitride (TiN) and a metal film of the likes of tungsten (W), and so on. The contact electrodes ch, which are provided correspondingly to the plurality of semiconductor columns 120, are connected to the lower ends of the plurality of semiconductor columns 120.

### Structure of Wiring Layers M0, M1 of Chip C_{M}

The wiring layers M0, M1 comprise: pluralities of wirings m0, m1; and the insulating layer 105 filled into peripheries of these pluralities of wirings m0, m1. The pluralities of wirings m0, m1 are electrically connected to either or both of the configurations in the memory cell array layer L_{MCA} and the configurations in the chip C_{P}, for example.

The plurality of wirings m0 may include for example the likes of a stacked film having stacked therein: a barrier conductive film of the likes of titanium nitride (TiN), tantalum nitride (TaN), or a stacked film of tantalum nitride (TaN) and tantalum (Ta); and a metal film of the likes of copper (Cu). Note that a part the plurality of wirings m0 function as the bit lines BL. As shown in FIG. 6, for example, the bit lines BL are arranged in the X-direction and extend in the Y-direction.

The plurality of wirings m1 are included. These plurality of wirings m1 may include for example a stacked film having stacked therein a barrier conductive film of the likes of titanium nitride (TiN) and a metal film of the likes of tungsten (W), and so on. Moreover, as shown in FIGS. 4 and 5, for example, these plurality of wirings m1 are electrically connected to the wiring m0 via a contact electrode V1.

### Structure of Chip Bonding Electrode Layer MB

The chip bonding electrode layer MB comprises: a plurality of the bonding electrodes P_{I1}; and the insulating layer 105 filled into peripheries of these plurality of bonding electrodes P_{I1}. The plurality of bonding electrodes P_{I1} are electrically connected to either or both of the configurations in the memory cell array layer L_{MCA} and the configurations in the chip C_{P}, for example.

The plurality of bonding electrodes P_{I1} may include for example the likes of a stacked film having stacked therein: a barrier conductive film p_{I1B} of the likes of titanium nitride (TiN), tantalum nitride (TaN), or a stacked film of tantalum nitride (TaN) and tantalum (Ta); and a metal film p_{I1M} of the likes of copper (Cu).

### Structure of Chip C_{P}

As shown in FIG. 4, for example, the chip C_{P} comprises: a semiconductor substrate (second substrate) 200; an electrode layer GC provided above the semiconductor substrate 200; wiring layers D0, D1, D2, D3, D4 provided above the electrode layer GC; and a chip bonding electrode layer DB provided above the wiring layers D0, D1, D2, D3, D4.

### Structure of Semiconductor Substrate 200 of Chip C_{P}

The semiconductor substrate 200 includes P-type silicon (Si) that includes a P-type impurity such as boron (B), for example. A surface of the semiconductor substrate 200 is provided with, for example: an N-type well region 200N including an N-type impurity such as phosphorus (P); a P-type well region 200P including a P-type impurity such as boron (B); a semiconductor substrate region 200S where the N-type well region 200N and P-type well region 200P are not provided; and an insulating region STI. A part of the P-type well regions 200P are provided in the semiconductor substrate region 200S, and a part of the P-type well regions 200P are provided in the N-type well region 200N. Each of the N-type well region 200N, the P-type well regions 200P provided in the N-type well region 200N and semiconductor substrate region 200S, and the semiconductor substrate region 200S functions as parts of a plurality of transistors Tr and a plurality of capacitors, and so on, configuring the peripheral circuit PC. The insulating region STI includes the likes of silicon oxide (SiO₂), for example, and extends in the Z-direction.

### Structure of Electrode Layer GC of Chip C_{P}

The electrode layer GC is provided on an upper surface of the semiconductor substrate 200 via an insulating layer 200G. The electrode layer GC includes: a plurality of electrodes gc facing the surface of the semiconductor substrate 200; and an insulating layer 205 filled into peripheries of these plurality of electrodes gc, and mainly composed of silicon oxide. Each of the regions of the semiconductor substrate 200 and the plurality of electrodes gc included in the electrode layer GC is connected to contact electrodes CS.

The respective plurality of electrodes gc included in the electrode layer GC function as gate electrodes of the plurality of transistors Tr, and so on, configuring the peripheral circuit PC.

The contact electrode CS extends in the Z-direction, and is connected at its lower end to an upper surface of the semiconductor substrate 200 or electrode gc. A connecting portion of the contact electrode CS and semiconductor substrate 200 is provided with an impurity region including an N-type impurity or P-type impurity. The contact electrode CS may include for example a stacked film having stacked therein a barrier conductive film of the likes of titanium nitride (TiN) and a metal film of the likes of tungsten (W), and so on.

### Structure of Wiring Layers D0, D1, D2, D3, D4 of Chip C_{P}

As shown in FIG. 4, for example, the wiring layers D0, D1, D2, D3, D4 comprise: pluralities of wirings d0, d1, d2, d3, d4; and the insulating layer 205 filled into peripheries of these pluralities of wirings d0, d1, d2, d3, d4. The pluralities of wirings d0, d1, d2, d3, d4 are electrically connected to either or both of the configurations in the memory cell array layer L_{MCA} and the configurations in the chip C_{P}, for example.

The pluralities of wirings d0, d1, d2 may include for example a stacked film having stacked therein a barrier conductive film of the likes of titanium nitride (TiN) and a metal film of the likes of tungsten (W), and so on.

The pluralities of wirings d3, d4 may include for example the likes of a stacked film having stacked therein: a barrier conductive film of the likes of titanium nitride (TiN), tantalum nitride (TaN), or a stacked film of tantalum nitride (TaN) and tantalum (Ta); and a metal film of the likes of copper (Cu).

### Structure of Chip Bonding Electrode Layer DB

The chip bonding electrode layer DB comprises: the plurality of the bonding electrodes P_{I2}; and the insulating layer 205 filled into peripheries of these plurality of bonding electrodes P_{I2}. The plurality of bonding electrodes P_{I2} are electrically connected to either or both of the configurations in the memory cell array layer L_{MCA} and the configurations in the chip C_{P}, for example.

The plurality of bonding electrodes P_{I2} may include for example the likes of a stacked film having stacked therein: a barrier conductive film p_{I2B} of the likes of titanium nitride (TiN), tantalum nitride (TaN), or a stacked film of tantalum nitride (TaN) and tantalum (Ta); and a metal film p_{I2M} of the likes of copper (Cu).

Note that when the metal films p_{I1M}, p_{I2M} of the likes of copper (Cu) are employed in the bonding electrode P_{I1} and bonding electrode P_{I2}, the metal film p_{I1M} and the metal film p_{I2M} become one metal film, so that identification of their boundary with each other becomes difficult. However, due to distortion of shape where the bonding electrode P_{I1} and bonding electrode P_{I2} have been bonded resulting from positional shift of bonding, and due to positional shift (generation of discontinuous places in side surfaces) of the barrier conductive films p_{I1B}, p_{I2B}, bonding structure can be identified. Moreover, when the bonding electrode P_{I1} and bonding electrode P_{I2} are formed by a damascene method, their respective side surfaces will have a tapered shape. Therefore, shape of a cross section along the Z-direction in a portion where the bonding electrode P_{I1} and bonding electrode P_{I2} have been bonded will be non-rectangular due to side walls being non-linearly shaped. Moreover, when the bonding electrode P_{I1} and bonding electrode P_{I2} are bonded, there will be a structure where each of a bottom surface, side surface, and upper surface of the Cu forming them will be covered by a barrier metal. In contrast, in a general wiring layer employing Cu, the upper surface of the Cu is provided with an insulating layer (of the likes of SiN or SiCN) functioning to prevent oxidation of the Cu, and is not provided with a barrier metal. Therefore, distinction from a general wiring layer is possible, even when positional shift of bonding has not occurred.

### Method of Manufacturing

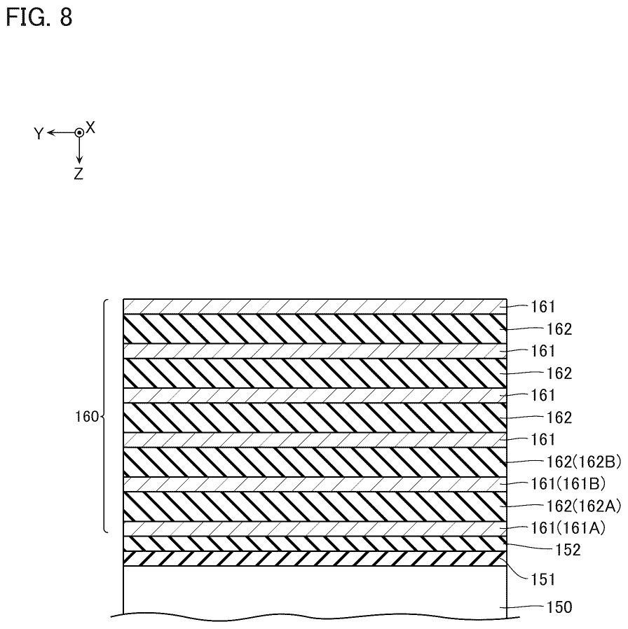

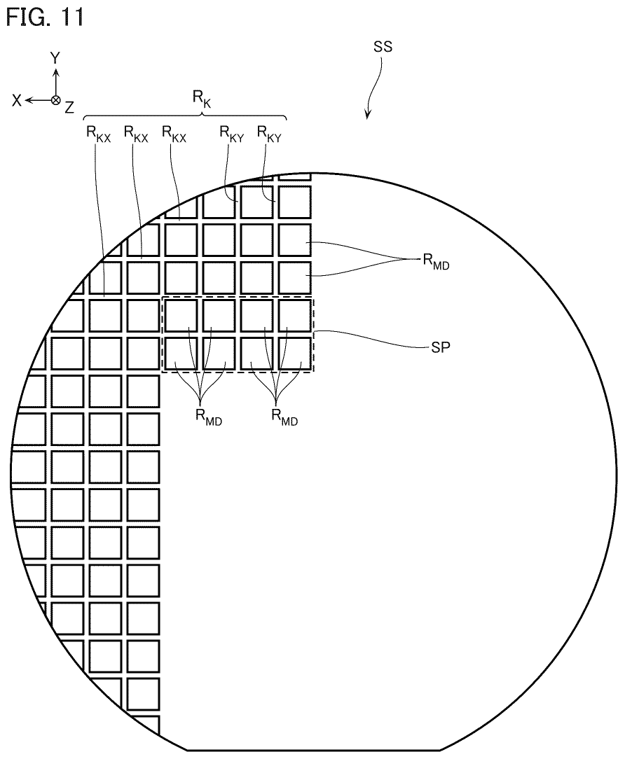

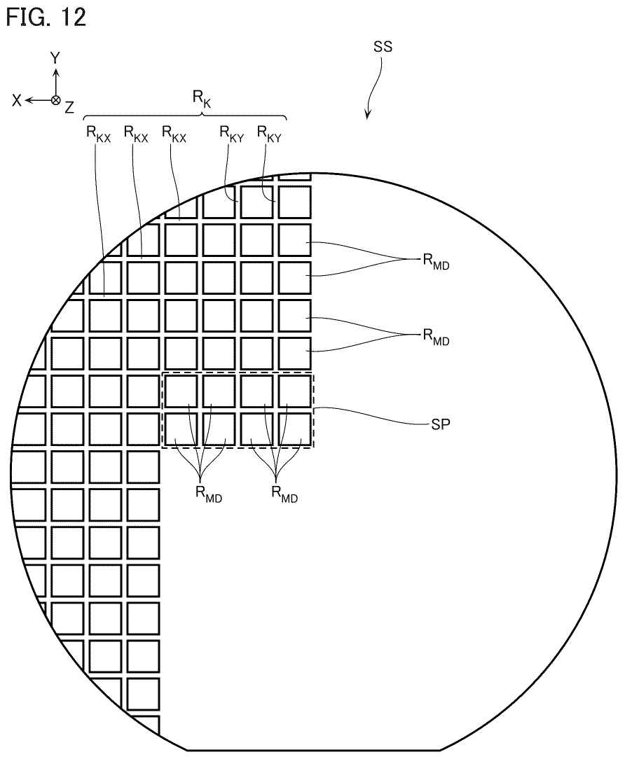

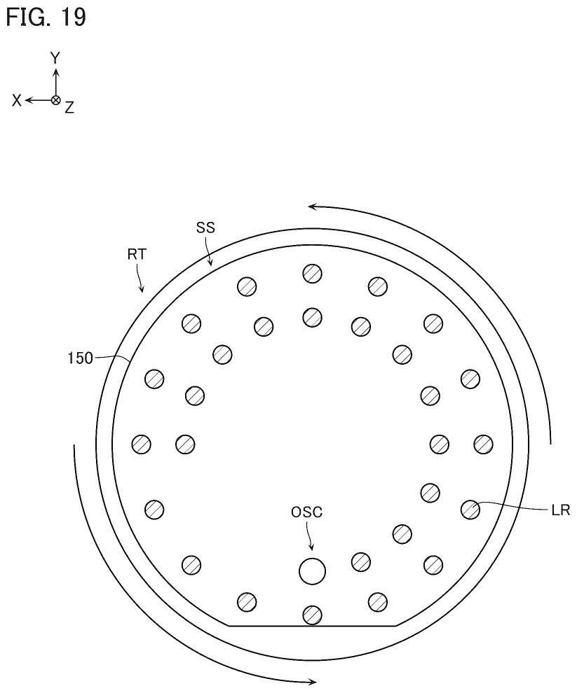

Next, a method of manufacturing a semiconductor device according to the first embodiment will be described with reference to FIGS. 8 to 28. FIGS. 8 to 10, 13 to 18, and 20 to 26 are schematic cross-sectional views for explaining same method of manufacturing. FIGS. 11 and 12 are schematic bottom views for explaining same method of manufacturing. FIGS. 19, 27, and 28 are schematic top views for explaining same method of manufacturing.

In same method of manufacturing, as shown in FIG. 8, first, the first substrate 150 is prepared. The first substrate 150, which is assumed to be a silicon substrate or silicon carbide substrate, is a substrate having light transmittance. In the present embodiment, “having light transmittance” refers to having a property that at least later-mentioned laser light will be transmitted. For example, transmittance rate of laser light may be set to 50% or more for the first substrate 150. Moreover, a substrate with a resistance rate of 1 to 100 Ω·cm (ohm centimeters), for example, may be used as the first substrate 150.

Next, both surfaces of the first substrate 150 are cleaned, and then an insulating layer 151 mainly composed of silicon nitride, or the like, is formed on the first substrate 150. The insulating layer 151 is formed using the likes of CVD (Chemical Vapor Deposition), for example. Layer thickness of the insulating layer 151, which may be 300 nm or less, may be 200 nm or less, and is preferably between 50 nm and 100 nm inclusive, may be set to 70 nm, for example.

Moreover, an insulating layer 152 of the likes of silicon oxide is formed on the insulating layer 151, for example. Layer thickness of the insulating layer 152 may be 300 nm or less, may be 200 nm or less, and may be preferably set to between 50 nm and 100 nm inclusive. The insulating layers 151, 152 are one example of a protective layer stacked in the first substrate. Note that as other embodiments, either one of the insulating layers 151, 152 may be formed, or neither of the insulating layers 151, 152 need be formed.

Next, as shown in FIG. 8, a metal layer (first layer) 161 mainly composed of a component whose extinction coefficient in an infrared region is greater than that of silicon, and a silicon oxide layer (second layer) 162 mainly composed of silicon oxide (SiO₂) are alternately stacked on the insulating layer 152 to form a stacked portion 160. A direction in which these metal layer (first layer) 161 and silicon oxide layer (second layer) 162 are stacked (Z-direction) is assumed to be a stacking direction (stacking direction intersecting the first substrate 150).

In the example of FIG. 8, the stacked portion 160 comprises six metal layers 161 and five silicon oxide layers 162. The silicon oxide layer 162 has upper and lower surfaces sandwiched by the metal layers 161. Note that in the stacked portion 160, a first metal layer 161 and a first silicon oxide layer 162 counted in order from a positive side in the Z-direction (a first substrate 150 side) are respectively assumed to be a metal layer 161A and silicon oxide layer 162A, and a second metal layer 161 and a second silicon oxide layer 162 counted in order from a positive side in the Z-direction (a first substrate 150 side) are respectively assumed to be a metal layer 161B and silicon oxide layer 162B.

The metal layer 161 may include a metal compound having light transmittance, from a viewpoint of suitably manufacturing the semiconductor device. Moreover, from a similar viewpoint, the metal layer 161 may include at least one of tin (Sn), magnesium (Mg), and zinc (Zn). Furthermore, from a similar viewpoint, the metal layer 161 may include at least one of antimony tin oxide (ATO), magnesium fluoride (MgF₂), and zinc sulfide (ZnS).

Extinction coefficient is a coefficient indicating to what extent light will be attenuated in the case of the light being incident on a substance, the greater a value of the extinction coefficient being, the more strongly the incident light being attenuated. Magnitude of extinction coefficient for two or more materials can be compared by fixing the wavelength of light incident on those materials at a certain value. For example, in the case where wavelength of light is in the infrared region in a vicinity of 1150 nm, the extinction coefficient in this range of wavelength will generally be zero for silicon, will exceed zero but be less than or equal to 1.3 for magnesium fluoride, and will exceed zero but be less than or equal to 2.2 for zinc sulfide. Similarly, for antimony tin oxide too, extinction coefficient in this range of wavelength will be greater than that of silicon. Moreover, transmission rate of light in this range of wavelength will generally be 60% or less for silicon, and 50% or less for antimony tin oxide. Similarly, for magnesium fluoride and zinc sulfide, too, transmission rate of light in this range of wavelength will be lower than that of silicon.

Layer thickness of the metal layer 161 may be set to 300 nm or less, may be set to 200 nm or less, and may be preferably set to between 50 nm and 100 nm inclusive. Layer thickness of the silicon oxide layer 162 may be set to 500 nm or less, may be set to 300 nm or less, may be set to 200 nm or less, and may be preferably set to between 100 nm and 150 nm inclusive. Melting point of the metal layer 161 may be set higher than melting point of the silicon oxide layer 162.

A film-forming method of each of the metal layer 161 and silicon oxide layer 162 is not particularly limited, but examples of the film-forming method include CVD, PVD (Physical Vapor Deposition) of the likes of sputtering, and so on.

Hereafter, a configuration comprising the first substrate 150, the insulating layers 151, 152, and the stacked portion 160 will be referred to as a first wafer SS.

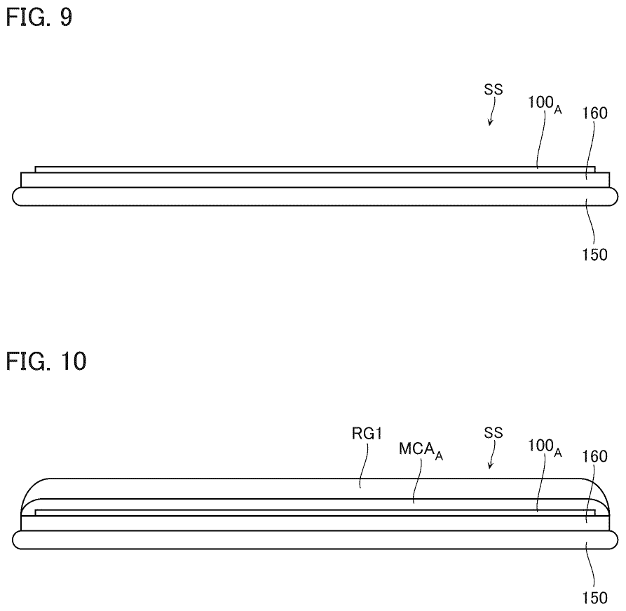

Next, as shown in FIG. 9, a conductive layer 100_{A} is formed on the stacked portion 160 by CVD, or the like. The conductive layer 100_{A} will later become the conductive layer 100 (source line SL) in the memory die MD. Then, as shown in FIG. 10, a plurality of silicon nitride layers and a plurality of silicon oxide layers are alternately stacked on the conductive layer 100_{A} by the likes of CVD to form a stacked body MCA_{A}. Then, the stacked body MCA_{A} is coated with a resist RG1.

Next, as shown in FIGS. 11 and 12, for example, patterning is performed by a means such as photolithography. During patterning, a stepper, or the like, is employed to sequentially perform transfers to the resist of a pattern (hereafter, referred to as a “shot pattern SP”) corresponding to a plurality of die regions R_{MD}, in an entire region in the first wafer SS. In the example illustrated, the shot pattern SP includes a pattern corresponding to a four-by-two arrangement of die regions R_{MD} in the X-direction and the Y-direction, that is, a total of eight die regions R_{MD}. Note that FIG. 11 exemplifies a state after execution of the 10^{th} transfer. FIG. 12 exemplifies a state after execution of the 11^{th} transfer.

Note that FIGS. 11 and 12 exemplify a calf region R_{K} provided between the plurality of die regions R_{MD}. The plurality of die regions R_{MD} are each a region that is to become part of the memory die MD, due to the die regions R_{MD} being individualized by later-mentioned dicing. The calf region R_{K} includes a dicing line. The calf region R_{K} comprises: a plurality of calf regions R_{KY} extending in the Y-direction along a part of the dicing lines and arranged in the X-direction; and a plurality of calf regions R_{KX} extending in the X-direction along a part of the dicing lines and arranged in the Y-direction.

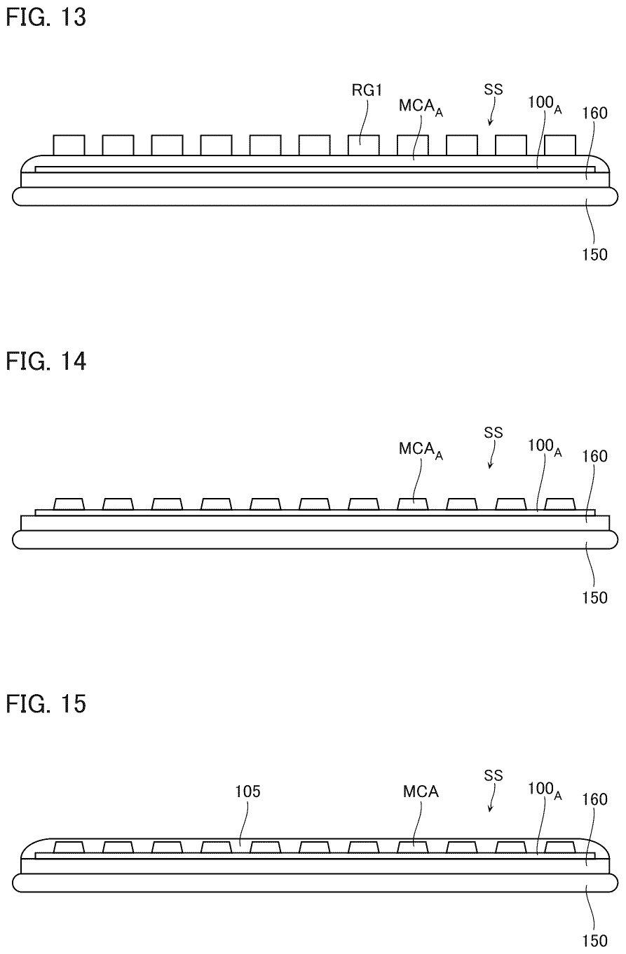

Next, as shown in FIG. 13, part of the resist RG1 is removed, and part of the stacked body MCA_{A} that had been covered by the resist RG1 exposed. This step is performed by a means such as wet etching, for example.

Then, as shown in FIG. 14, the stacked body MCA_{A} is divided every memory cell array MCA (every memory plane MP). In this step, removal of the silicon oxide layer in the stacked body MCA_{A} by a method such as RIE (Reactive Ion Etching), removal of the silicon nitride layer in the stacked body MCA_{A} by a method such as RIE, and slimming of the resist RG1 by a method such as wet etching, are repeatedly executed. This step results in there being formed in each silicon nitride layer in the stacked body MCA_{A} a portion corresponding to the terrace portion (a portion that, viewed from a negative side in the Z-direction, does not overlap another silicon nitride layer). Moreover, repetition of this step results in the stacked body MCA_{A} being divided every memory cell array MCA (every memory plane MP).

Next, as shown in FIG. 15, the plurality of memory cell arrays MCA are formed. The memory cell array MCA can be formed by the following steps, for example. First, a region between the stacked bodies MCA_{A} is filled in by the insulating layer 105. Next, a memory hole penetrating the stacked body MCA_{A} and reaching the conductive layer 100_{A} is formed at a plurality of positions corresponding to the plurality of semiconductor columns 120. Next, the gate insulating film 130, semiconductor column 120, and so on, are formed in these plurality of memory holes. Next, a trench is formed at a plurality of positions corresponding to the plurality of inter-block insulating layers ST. Next, the silicon nitride layers in the stacked body MCA_{A} are removed by a method such as wet etching via the plurality of trenches, and a plurality of cavities formed. Next, the plurality of conductive layers 110 are formed by a method such as CVD. Next, the inter-block insulating layer ST is formed inside the trench.

Next, the wiring layers CH, Vy, M0, M1, MB, and so on, described with reference to the likes of FIGS. 4 and 5, are formed. This step is performed by the likes of a damascene process, for example.

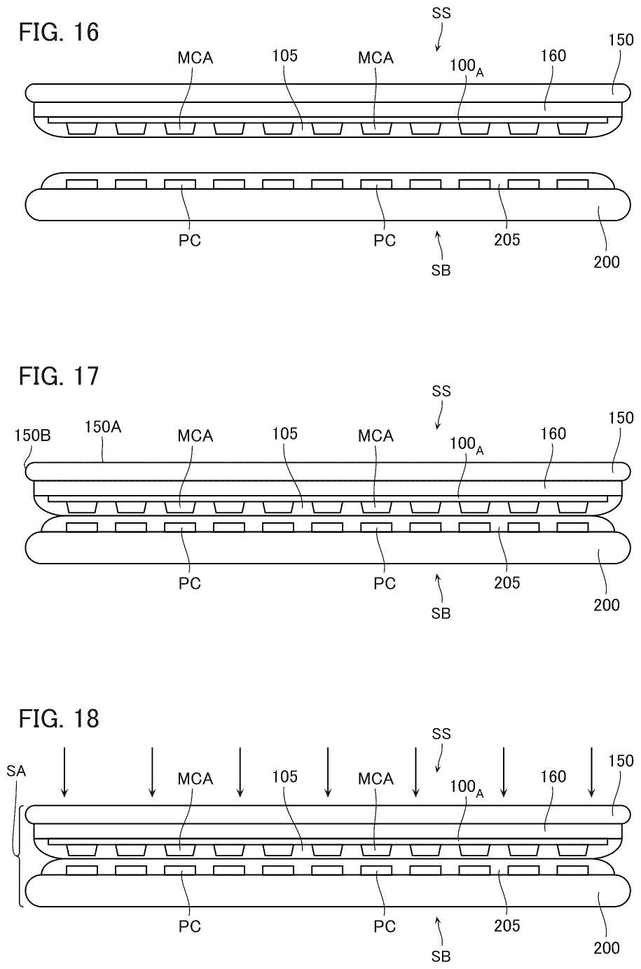

Next, as shown in FIG. 16, a second wafer SB which is a separate body from the first wafer SS, is formed. Specifically, a plurality of the peripheral circuits PC including the transistors Tr (FIG. 5) as a second element, are formed on the semiconductor substrate 200. The plurality of peripheral circuits PC are formed so as to each correspond to the plurality of memory cell arrays MCA, for example. Moreover, the insulating layer 205 covering the peripheral circuit PC is formed. The bonding electrode P_{I2} electrically connected to the transistor Tr, and so on, of the peripheral circuit PC is formed in a surface of the insulating layer 205.

Next, as shown in FIGS. 16 and 17, the first wafer SS and the second wafer SB are bonded. Specifically, as shown in FIG. 16, a surface where the memory cell arrays MCA, and so on, are formed of the first wafer SS is faced against a surface where the peripheral circuits PC, and so on, are formed of the second wafer SB. Next, as shown in FIG. 17, the first wafer SS and the second wafer SB are bonded. In this step, the insulating layer 105 in the first wafer SS and the insulating layer 205 in the second wafer SB are joined.

Note that when the first wafer SS and the second wafer SB are bonded, the first wafer SS and the second wafer SB are arranged so that the plurality of bonding electrodes P_{I1} and the plurality of bonding electrodes P_{I2} overlap viewed in the Z-direction.

After the insulating layers 105, 205 have been joined, annealing processing is performed, whereby pairs of the bonding electrodes P_{I1}, P_{I2} are joined by Cu-Cu joints, for example. This results in that along with mutually corresponding memory cell arrays MCA and peripheral circuits PC being electrically connected, the first wafer SS and the second wafer SB are bonded (the first substrate 150 and the semiconductor substrate 200 are bonded via the bonding electrodes P_{I1} and bonding electrodes P_{I2}). In the following description, a structure where the first wafer SS and the second wafer SB have been bonded will be referred to as a bonded body SA.

As shown in FIG. 17, in the present embodiment, an outer peripheral portion 150B of the first substrate 150 has not undergone trimming processing. Specifically, in the first substrate 150, the outer peripheral portion 150B configuring an outer peripheral portion of a main body portion 150A has a rounded shape in cross-sectional view. The outer peripheral portion 150B does not have a notched shape in cross-sectional view, and has not undergone trimming processing to form such a notched shape, for example. Such trimming processing need not be performed in a period from the step of preparing the first substrate 150 to the step of bonding the first wafer SS and the second wafer SB, need not be performed up to a later-mentioned reutilization step, and need not be performed over an entirety of manufacturing steps of the semiconductor device, for example.

As shown in FIG. 18, laser light is transmitted through the first substrate 150 to irradiate the stacked portion 160, in the bonded body SA of the first wafer SS and the second wafer SB. Wavelength of the laser light is preferably in a range of 780 to 4000 nm, and more preferably in a range of 1100 to 1700 nm. A semiconductor laser or solid-state laser (Nd:YAG, or the like), for example, may be employed as the laser light.

Irradiating mode of the laser light is not particularly limited, but pulse-like irradiation is preferable, for example. As shown in FIG. 19, for example, the bonded body SA of the first wafer SS and the second wafer SB can be placed on a rotationally drivable stage RT, and can sequentially undergo pulse-like irradiation with laser light from a laser oscillator OSC, while the stage RT is rotated.

That is, by irradiating the first wafer SS with laser light at fixed time intervals while rotating the stage RT, it is possible to irradiate with the laser a plurality of positions LR along a certain circle centered on a rotational axis of the stage RT. Moreover, by bringing an irradiating position of the laser closer to the rotational axis of the stage RT or distancing the irradiating position of the laser from the rotational axis of the stage RT, it is possible to irradiate with the laser a plurality of positions LR along another circle centered on the rotational axis of the stage RT. Such a method enables laser light to be irradiated in a concentric circular manner on an entire surface of the first wafer SS.

Pitch of the irradiating position of the laser light can be set to a 10-or-so μm interval, for example. Pulse frequency can be set to between 10 kHz and 100 kHz inclusive, for example.

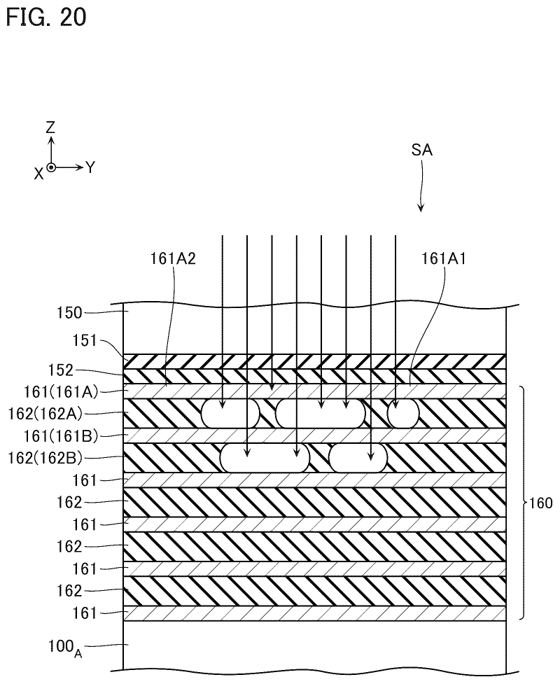

By irradiating the first wafer SS with laser light, temperature of the silicon oxide layer 162 in the stacked portion 160 formed in the first substrate 150 sharply rises, and melting, evaporation, or sublimation (hereafter, referred to as “evaporation, and so on”) occurs as shown in FIG. 20, whereby the stacked portion 160 undergoes cleavage.

Specifically, as shown in FIG. 20, irradiation with laser light causes the laser light that has irradiated the bonded body SA to be transmitted through the first substrate 150 and the insulating layers 151, 152, and reach the stacked portion 160. In the stacked portion 160, the laser light is further transmitted through a first metal layer 161A counted from an upper side, and reaches the silicon oxide layer 162A. Moreover, a part of the laser light that has been transmitted through the silicon oxide layer 162A is transmitted through a second metal layer 161B counted from the upper side, and reaches the silicon oxide layer 162B.

Moreover, by the silicon oxide layer 162A being disposed between the two metal layers 161A, 161B, for example, a part of the laser light that has been transmitted through the metal layer 161A will be reflected by the metal layer 161B.

The silicon oxide layers 162A, 162B absorb the laser light that has reached them, and emit heat, thereby causing evaporation, and so on, to occur.

The laser light gradually attenuates by being absorbed by a plurality of layers. Hence, in the stacked portion 160, a first silicon oxide layer 162A from the upper side more easily evaporates, and so on, than a second silicon oxide layer 162B counted from the upper side. In the example of FIG. 20, evaporation, and so on, occurs in the first and second silicon oxide layers 162A, 162B counted from the upper side.

Evaporation, and so on, of the silicon oxide layers 162A, 162B causes a stress difference to occur between a neighboring portion of where they have evaporated, and so on, and a flanking portion of the neighboring portion. For example, evaporation, and so on, of the silicon oxide layer 162A causes a stress difference to occur between a neighboring portion 161A1 of a portion where evaporation, and so on, has occurred in the silicon oxide layer 162A, and a flanking portion 161A2 located in a flank of the neighboring portion 161A1, in the metal layer 161A (such a stress difference may also occur in the insulating layers 152, 151, for example). Moreover, due to this stress difference, a strain occurs between the neighboring portion 161A1 and flanking portion 161A2, and, for example, a boundary surface between the silicon oxide layer 162A and the metal layer 161A or between the metal layer 161A and the insulating layer 152, undergoes cleavage.

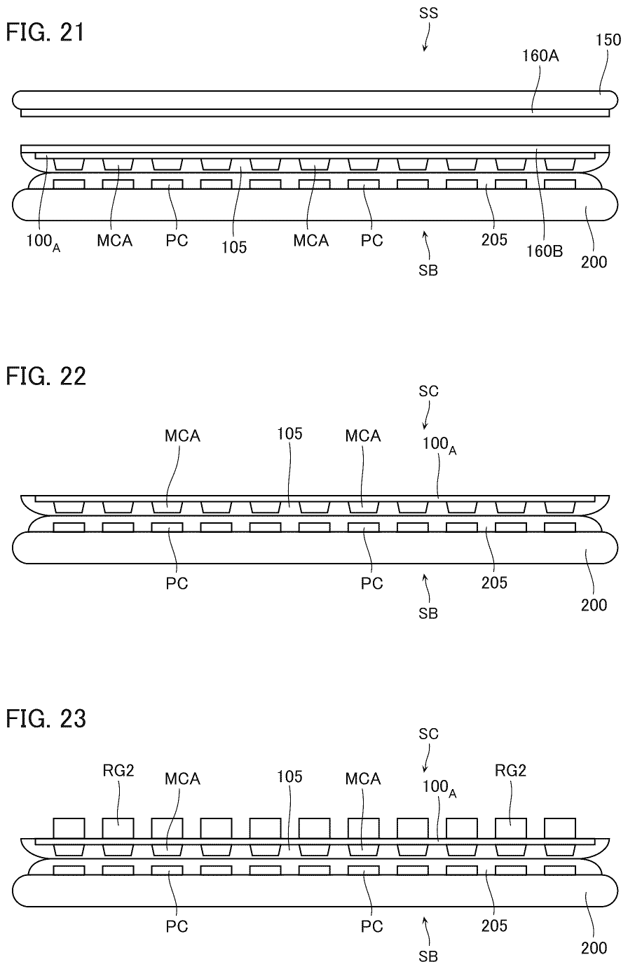

Due to the cleavage that has occurred in this way, as shown in FIG. 21, the first substrate 150 will be detached from other configurations in the first wafer SS (configurations formed later than the stacked portion 160 in the first wafer SS). At this time, all or a part of the insulating layers 151, 152, and a part of the metal layers 161 and silicon oxide layers 162 will accompany the first substrate 150 as an accompanying portion 160A, and will be detached along with the first substrate 150. Moreover, others of the metal layers 161 and silicon oxide layers 162 will remain on a second wafer SB side as a remaining portion 160B. Hereafter, configurations in the first wafer SS remaining on the second wafer SB side will be referred to as a structure SC.

Next, the remaining portion 160B that has remained in the structure SC is ground and removed by the likes of CMP (Chemical Mechanical Polishing). As a result, as shown in FIG. 22, the conductive layer 100_{A} is exposed on an upper surface of the second wafer SB.

Next, as shown in FIG. 23, a resist RG2 having a pattern matched to dispositions of the individual memory cell arrays MCA (memory planes MP) is formed on the conductive layer 100_{A}. When forming the resist RG2, for example, the resist is coated, patterning is performed by a method of the kind described with reference to FIGS. 11 and 12, and part of the resist is removed by a method such as wet etching.

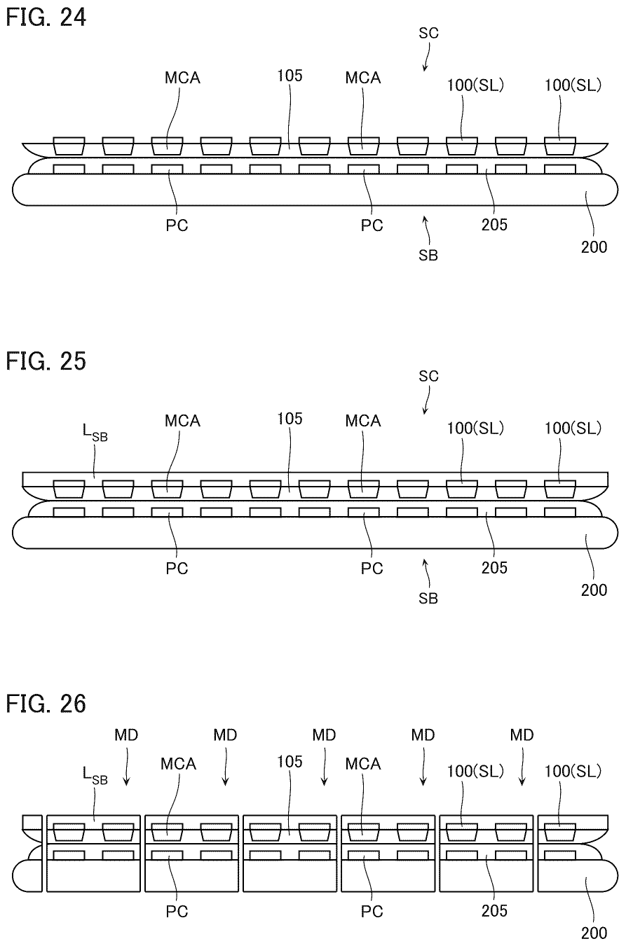

Next, as shown in FIG. 24, etching processing of the conductive layer 100_{A} is performed via the resist RG2, whereby a plurality of the conductive layers 100 (source lines SL) separated every individual memory cell array MCA, are formed.

After the conductive layers 100 have been formed, the resist RG2 is removed by ashing processing using oxygen plasma, or the like. Then, as shown in FIG. 25, the substrate layer L_{SB} is formed.

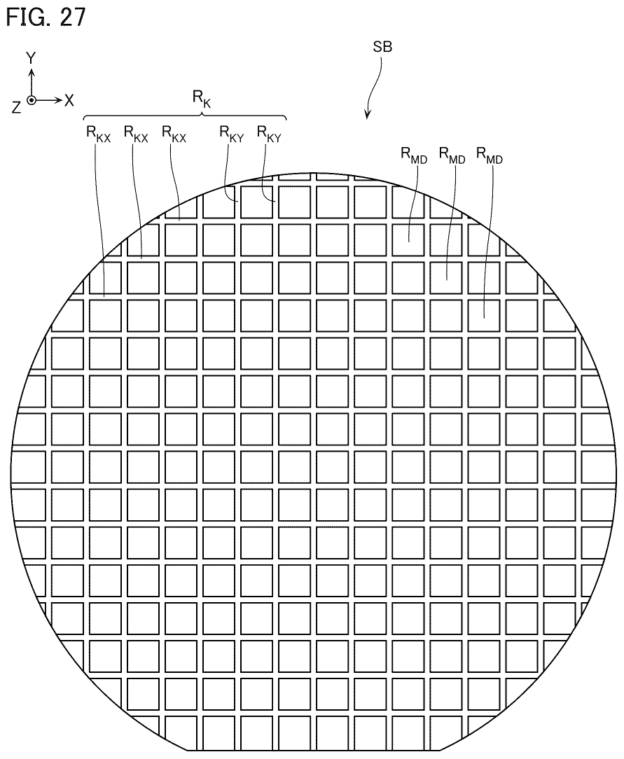

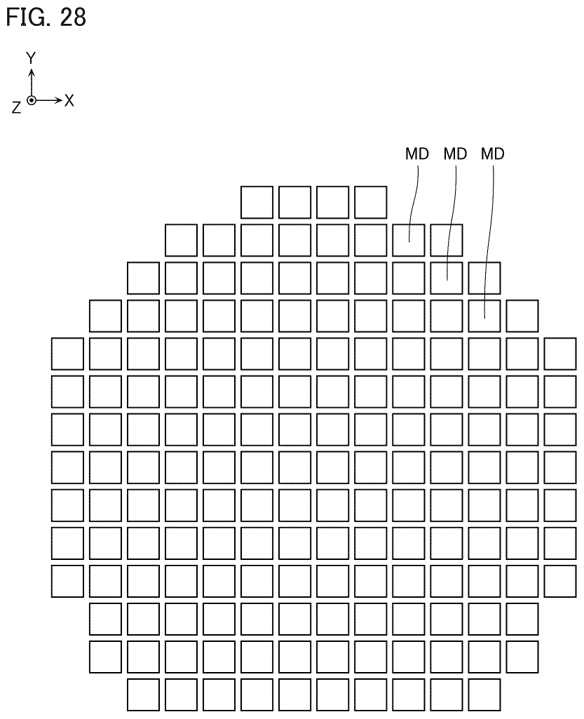

Next, as shown in FIG. 26, individualization is performed, and a plurality of the memory dies MD are formed. That is, the structure SC and the second wafer SB are provided with the plurality of die regions R_{MD}, as shown in FIG. 27, for example. Moreover, the calf regions R_{KX}, R_{KY} are provided between these plurality of die regions R_{MD}. In the step of individualization, for example, dicing is performed along the dicing lines in the calf regions R_{KX}, R_{KY}, and, as shown in FIG. 28, a bonded body of the structure SC and the second wafer SB is individualized for each of the plurality of die regions R_{MD}. Each individualized configuration becomes a memory die MD.

Note that for convenience of illustration, in the example of FIG. 3, four memory cell arrays MCA (memory planes MP) are provided in each memory die MD, and in the example of FIG. 26, two memory cell arrays MCA (memory planes MP) are provided in each memory die MD. However, the number of memory cell arrays MCA (memory planes MP) in each memory die MD is appropriately adjustable.

Note that by performing the following reutilization step, the first substrate 150 detached in the step described with reference to FIG. 21 can be employed in manufacturing of a new memory die MD.

In the reutilization step, the accompanying portion 160A accompanying the first wafer SS side due to cleavage of the stacked portion 160 (refer to FIG. 21) may be removed by being ground using a polishing pad. Moreover, in the reutilization step, the accompanying portion 160A may be removed by the likes of wet etching.

Removing the accompanying portion 160A from the first substrate 150, and then re-executing the step described with reference to FIG. 8 and subsequent steps makes it possible for the first substrate 150 to be used a plurality of times in manufacturing steps of the memory die MD.

### Advantages

In a method of manufacturing a semiconductor device, in the case where a substrate having a certain layer, and another substrate are bonded, and the certain layer is irradiated with a laser light to detach the substrate, there is a possibility that a local stress will occur in the certain layer or its close vicinity, and that a crystalline fault, structural damage, or the like, will occur in the substrate or a structure formed in the substrate. Moreover, in the case where, after a step of detaching the two substrates, it is tentatively attempted to reutilize the substrate that had had the certain layer, there is a need for a portion where the previously-mentioned crystalline fault, structural damage, or the like (hereafter, referred to as damage), has occurred, to be deeply ground, for example, in order to remove it. By doing so, the substrate to be reutilized will get thinner, and the number of times the substrate can be reutilized will fall.

As described with reference to FIG. 8, the method of manufacturing a semiconductor device according to the present embodiment includes a step of alternately stacking the metal layer 161 (first layer) mainly composed of a component whose extinction coefficient in an infrared region is greater than that of silicon and the silicon oxide layer 162 (second layer) mainly composed of silicon oxide on the first substrate 150, and thereby forming the stacked portion 160. Moreover, as described with reference to FIG. 15, it includes a step of forming the memory cell array MCA (first element) and the bonding electrode P_{I1} (first bonding electrode) in the first wafer SS. Moreover, as described with reference to FIG. 16, it includes a step of forming the transistor Tr (second element) and the bonding electrode P_{I2} in the second wafer SB. Moreover, as described with reference to FIG. 17, it includes a step of bonding the first wafer SS and the second wafer SB via the bonding electrode P_{I1} and the bonding electrode P_{I2}. Moreover, as described with reference to FIGS. 18 to 20, it includes a step of transmitting a laser light through the first substrate 150 to irradiate the stacked portion 160 with the laser light, and thereby induce cleavage in the stacked portion 160.

Such a configuration makes it possible to cause laser light to be absorbed by the silicon oxide layer 162 (second layer) to make evaporation, and so on, occur therein, and enables a stress difference to be generated in a periphery of a portion where the evaporation, and so on, has occurred, and the first substrate 150 to be detached. Moreover, since the metal layers 161 (first layers) and silicon oxide layers 162 (second layers) are alternately stacked, it is made possible for cracking, or the like, that has occurred in the silicon oxide layer 162 (second layer) to be stopped by the metal layer 161 (first layer), whereby it can be suppressed that damage extends to the likes of the first substrate 150 or memory cell array MCA (first element). Hence, in the case where reutilization of the first substrate 150 is supposed, it can be suppressed that grinding of the first substrate 150 gets deep, and can be suppressed that the number of times the substrate 150 can be reutilized falls, for example. Furthermore, when a plurality of the metal layers 161 and silicon oxide layers 162 are alternately stacked, a volume in which evaporation, and so on, occurs in the silicon oxide layers 162 can be increased, so that cleavage in the stacked portion 160 can be suitably rendered.

Moreover, in the present embodiment, the first substrate 150 is a silicon substrate or a silicon carbide substrate. Such a configuration enables evaporation, and so on, to be effectively caused in the silicon oxide layer 162, due to laser light being suitably transmitted through the first substrate 150.

Moreover, as described with reference to FIG. 8, in the present embodiment, the metal layer 161 (first layer) includes a metal compound having light transmittance.

Such a configuration enables laser light to be suitably transmitted through the metal layer 161, and enables evaporation, and so on, to be effectively caused in the silicon oxide layer 162. Moreover, it enables extension of damage to the first substrate 150 or memory cell array MCA with evaporation, and so on, of the silicon oxide layer 162, to be further suppressed by the metal layer 161.

Moreover, as described with reference to FIG. 8, in the present embodiment, the metal layer 161 (first layer) includes at least one of tin, magnesium, and zinc. Furthermore, the metal layer 161 (first layer) includes at least one of antimony tin oxide, magnesium fluoride, and zinc sulfide.

As mentioned above, these materials have light transmittance, and have an extinction coefficient in an infrared region greater than that of silicon. Hence, such a configuration enables laser light to be more suitably transmitted through the metal layer 161 (first layer), and enables evaporation, and so on, to be more effectively caused in the silicon oxide layer 162 (second layer).

Now, if, in the case of a bonded body obtained by bonding a wafer including a memory cell array MCA and wafer including a peripheral circuit PC, a substrate in the wafer including the memory cell array MCA is removed from the bonded body by being ground, then there is a risk of thickness of an outer peripheral portion of the substrate getting extremely thin, and the outer peripheral portion breaking midway through the grinding. Therefore, there is a technology where trimming processing is priorly performed on the outer peripheral portion to suppress breakage of the outer peripheral portion.

On the other hand, in the present embodiment, since the stacked portion 160 is cleaved by laser light being irradiated on the stacked portion 160, a step for grinding the first substrate 150 to remove it, is not included. Hence, the outer peripheral portion 150B of the first substrate 150 does not undergo trimming processing.

Such a configuration enables the semiconductor device to be efficiently manufactured since a step of performing trimming processing of the outer peripheral portion 150B of the first substrate 150 is not required.

Moreover, as described with reference to FIG. 8, in the present embodiment, the insulating layers 151, 152 are stacked on the first substrate 150, prior to the metal layers 161 (first layers) and silicon oxide layers 162 (second layers) being alternately stacked on the first substrate 150.

Such a configuration enables extension of damage to the first substrate 150 with evaporation, and so on, of the silicon oxide layer 162 (second layer) to be more suitably suppressed by the insulating layers 151, 152. Moreover, it enables transmission to the first substrate 150 of heat generated by laser light being absorbed by the metal layer 161 or silicon oxide layer 162, to be suppressed.

Moreover, melting point of the metal layer 161 is higher than melting point of the silicon oxide layer 162.

Such a configuration enables evaporation, and so on, to be more preferentially caused in the silicon oxide layer 162 than in the metal layer 161 when the stacked portion 160 is irradiated with laser light. Moreover, it enables extension of damage to the first substrate 150 or memory cell array MCA (first element) to be suppressed by the metal layer 161.

### Second Embodiment

The method of manufacturing a semiconductor device according to the first embodiment may be appropriately adjusted. A step of reutilizing the first substrate 150 to manufacture a memory die MD2 will be described below as a second embodiment. Note that in the second embodiment, identical symbols will be employed for parts the same as in the first embodiment, and duplicated descriptions of structures, steps, actions, and advantages of those parts will be omitted.

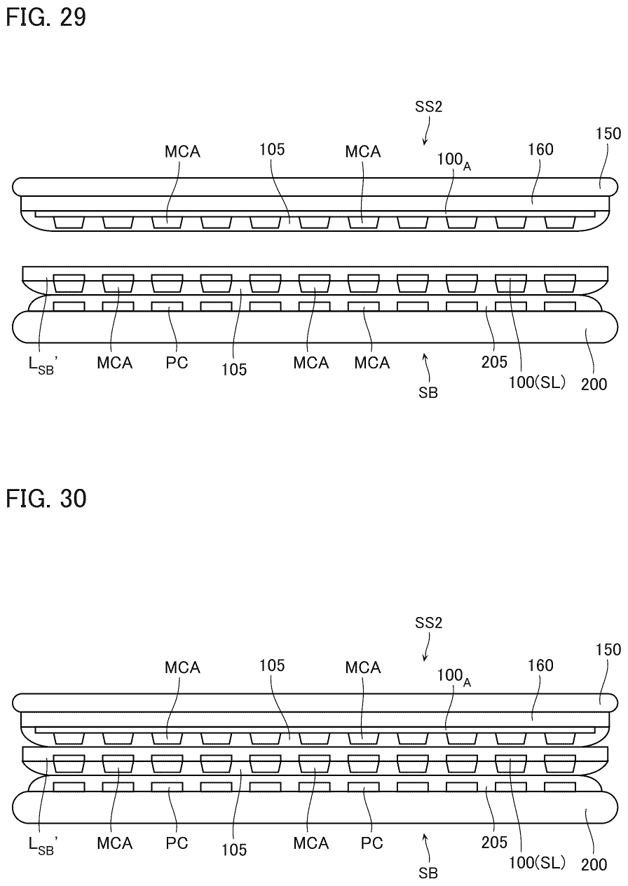

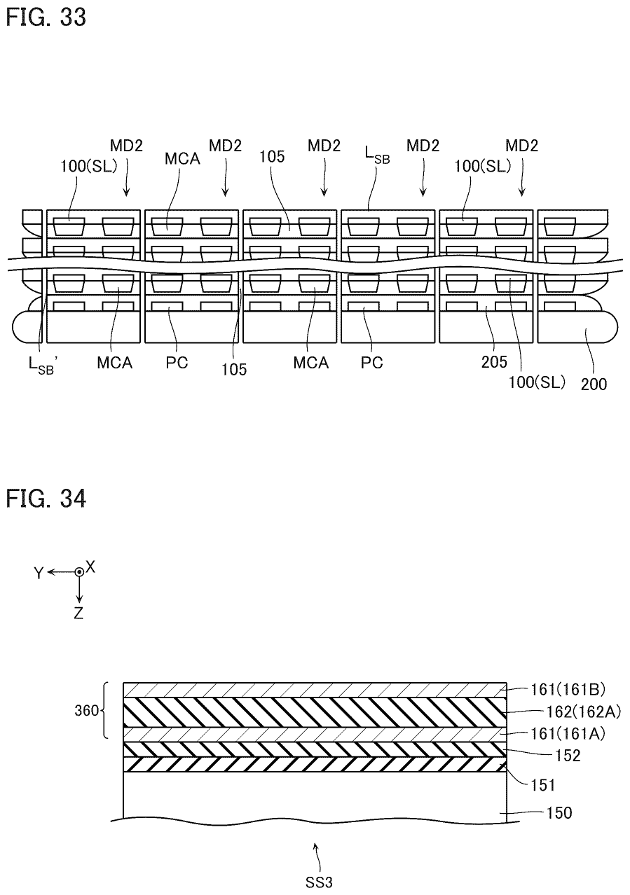

FIGS. 29 to 33 are schematic cross-sectional views for explaining a method of manufacturing a semiconductor device according to the second embodiment.

The method of manufacturing a semiconductor device according to the second embodiment executes up to the step described with reference to FIG. 25 of the method of manufacturing a semiconductor device according to the first embodiment. However, in the step described with reference to FIG. 25, a substrate layer L_{SB}′ is formed instead of the substrate layer L_{SB}. The substrate layer L_{SB}′ is basically configured similarly to the substrate layer L_{SB}. However, an upper surface of the substrate layer L_{SB}′ has formed therein a configuration similar to the bonding electrodes P_{I1}, P_{I2}, instead of the external pad electrode P_{X}.

Next, steps similar to the steps described with reference to FIGS. 8 to 16 are executed, and a wafer SS2 is formed. The wafer SS2 comprises a similar structure to the first wafer SS.

Next, as shown in FIGS. 29 and 30, the substrate layer L_{SB}′ and the wafer SS2 are bonded. This step is executed similarly to the steps described with reference to FIGS. 16 and 17.

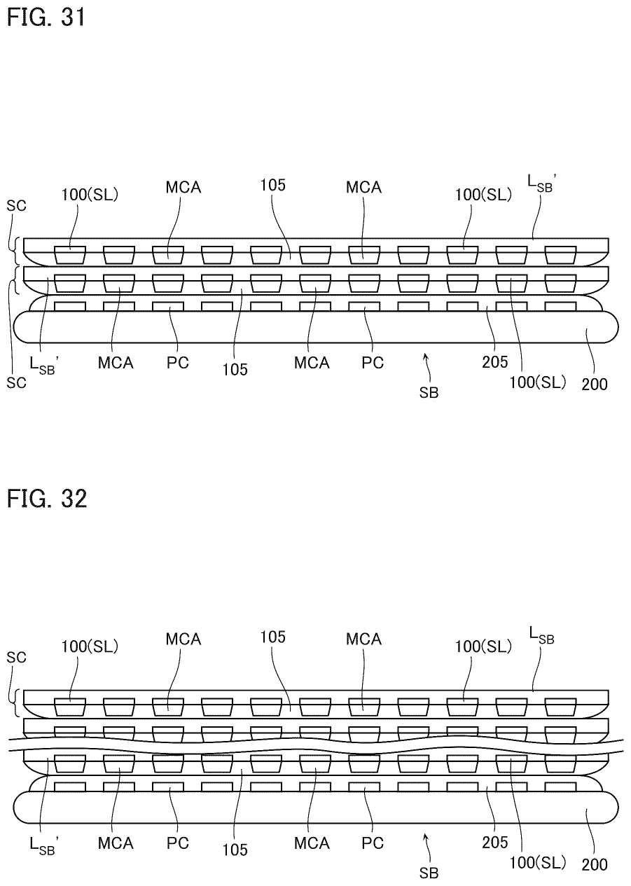

Next, steps similar to the steps described with reference to FIGS. 18 to 25 are executed. However, in the step described with reference to FIG. 25, the substrate layer L_{SB}′ is formed instead of the substrate layer L_{SB}. As a result, as shown in FIG. 31, a bonded body of a first structure SC bonded to the upper surface of the second wafer SB, and a second structure SC bonded to an upper surface of this first structure SC, is formed.

Similarly, thereafter, steps similar to the steps described with reference to FIGS. 8 to 25 are repeatedly executed, whereby, as shown in FIG. 32, a bonded body of a plurality of the structures SC bonded to the second wafer SB, is formed.

Next, steps similar to the steps described with reference to FIGS. 26 to 28 are executed, the bonded body of the plurality of structures SC bonded to the second wafer SB undergoes individualization, and a plurality of the memory dies MD2 are formed.

### Third Embodiment

Configuration of the stacked portion 160 according to the first embodiment may be appropriately adjusted. A stacked portion 360 being a different configuration from the stacked portion 160 will be described below as a third embodiment. Note that in the third embodiment, identical symbols will be employed for parts the same as in the first embodiment, and duplicated descriptions of structures, steps, actions, and advantages of those parts will be omitted.

FIG. 34 is a schematic cross-sectional view for explaining a method of manufacturing a semiconductor device according to the third embodiment.

The method of manufacturing a semiconductor device according to the third embodiment is basically executed similarly to the method of manufacturing a semiconductor device according to the first embodiment. However, in the third embodiment, in a step corresponding to FIG. 8, the stacked portion 360 is formed instead of the stacked portion 160. The stacked portion 360 basically comprises a similar configuration to the stacked portion 160. A configuration comprising the first substrate 150, the insulating layers 151, 152, and the stacked portion 360 will be referred to as a first wafer SS3.

However, the stacked portion 360 comprises only two metal layers 161 and only a single silicon oxide layer 162.

### Other Embodiments

That concludes description of the methods of manufacturing a semiconductor device according to the first through third embodiments. However, these configurations are merely exemplifications, and specific configurations may be appropriately adjusted.

For example, the above embodiments have exemplified the stacked portion 160 comprising six metal layers 161 and five silicon oxide layers 162, or stacked portion 360 comprising two metal layers 161 and one silicon oxide layer 162. However, the number of metal layers (first layers) and silicon oxide layers (second layers) in the stacked portion is appropriately adjustable. For example, the stacked portion may be configured stacking three through five metal layers 161 and two through four silicon oxide layers 162 on the insulating layer 152. Moreover, the stacked portion may be configured stacking seven or more metal layers 161 and six or more silicon oxide layers 162 on the insulating layer 152.

Moreover, the above embodiments have described examples applied to a FeFET or NAND flash memory as the semiconductor device being manufactured. However, technology described in the present specification may also be applied to a configuration other than NAND flash memory, such as NOR flash memory, for example. Moreover, technology described in the present specification may also be applied to a configuration other than flash memory, such as DRAM, for example. Moreover, technology described in the present specification may also be applied to a configuration other than memory, such as an arithmetic unit, for example.

### Others

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A method of manufacturing a semiconductor device, including the steps of:
alternately stacking a first layer mainly composed of a component whose extinction coefficient in an infrared region is greater than that of silicon and a second layer mainly composed of silicon oxide on a first wafer having a first substrate, and thereby forming a stacked portion in the first wafer;
forming a first element and a first bonding electrode in the first wafer;
forming a second element and a second bonding electrode in a second wafer;
bonding the first wafer and the second wafer via the first bonding electrode and the second bonding electrode; and
transmitting a laser light through the first substrate to irradiate the stacked portion with the laser light, and thereby induce cleavage in the stacked portion.

2. The method of manufacturing a semiconductor device according to claim 1, wherein
the first substrate is a silicon substrate or a silicon carbide substrate.

3. The method of manufacturing a semiconductor device according to claim 1, wherein
the first layer includes a metal compound having light transmittance.

4. The method of manufacturing a semiconductor device according to claim 1, wherein
the first layer includes at least one of tin, magnesium, and zinc.

5. The method of manufacturing a semiconductor device according to claim 4, wherein
the first layer includes at least one of antimony tin oxide, magnesium fluoride, and zinc sulfide.

6. The method of manufacturing a semiconductor device according to claim 1, wherein
an outer peripheral portion of the first substrate has not undergone trimming processing.

7. The method of manufacturing a semiconductor device according to claim 1, wherein
prior to the first layer and the second layer being alternately stacked on the first wafer, a protective layer is stacked on the first substrate.

8. The method of manufacturing a semiconductor device according to claim 1, wherein
the first element comprises:
a plurality of gate electrodes stacked in a stacking direction intersecting the first substrate;
a semiconductor column extending in the stacking direction; and
a gate insulating film provided between the plurality of gate electrodes and the semiconductor column.

9. The method of manufacturing a semiconductor device according to claim 8, wherein
the gate insulating film includes: an electric charge accumulating film; or a ferroelectric film mainly composed of at least one of silicon, aluminum, hafnium, and zirconium.

10. The method of manufacturing a semiconductor device according to claim 8, wherein
the semiconductor column is mainly composed of polycrystalline silicon.

11. The method of manufacturing a semiconductor device according to claim 8, wherein
the gate electrode is mainly composed of at least one of polycrystalline silicon, tungsten, molybdenum, and titanium nitride.

12. The method of manufacturing a semiconductor device according to claim 1, wherein
a wavelength of the laser light is in a range of 780 to 4000 nm.

13. The method of manufacturing a semiconductor device according to claim 11, wherein
a wavelength of the laser light is in a range of 1100 to 1700 nm.

14. The method of manufacturing a semiconductor device according to claim 1, wherein
subsequent to the step of inducing cleavage in the stacked portion, the second wafer is individualized into a plurality of chips.

15. The method of manufacturing a semiconductor device according to claim 1, wherein
a melting point of the first layer is higher than a melting point of the second layer.
